(19) United States
(12) Patent Application Publication
(10) Pub. No.: US 2025/0316567 A1
(43) Pub. Date: Oct. 9, 2025

(54) MOUNTING SUBSTRATE AND MOUNTING SUBSTRATE MANUFACTURING METHOD

(71) Applicant: Panasonic Intellectual Property Management Co., Ltd., Osaka (JP)

(72) Inventors: Takayoshi NIRENGI, Osaka (JP); Tsutomu AISAKA, Osaka (JP); Kiyoshi YAMAKOSHI, Osaka (JP); Akihiro OISHI, Osaka (JP); Jumpei IWANAGA, Osaka (JP); Tomohiro NAKAGAWA, Hyogo (JP)

(21) Appl. No.: 18/865,595

(22) PCT Filed: Mar. 9, 2023
(86) PCT No.: PCT/JP2023/009111

§ 371 Date: Nov. 13, 2024

(30) Foreign Application Priority Data
May 20, 2022 (JP) 2022-083431

(51) Int. Cl. H01L 23/498; H01L 21/48

(52) U.S. Cl. CPC H01L 23/49811; H01L 21/4846; H01L 23/49827

(57) ABSTRACT

A mounting substrate includes: an insulating layer; and a plurality of conductive bumps arranged on or above the insulating layer. A variation in height position between a plurality of end faces of the plurality of conductive bumps on a side opposite to the insulating layer is smaller than a variation in height position between a plurality of end faces of the plurality of conductive bumps on a side where the insulating layer is located.

### TECHNICAL FIELD

The present disclosure relates to a mounting substrate and a mounting substrate manufacturing method.

### BACKGROUND ART

Flip-chip technology using Cu (copper) pillar bumps is known as one of the technologies for mounting a semiconductor chip on a substrate (see, for example, Patent Literature (PTL) 1). Cu pillar bumps are formed, for example, by a semi-additive process (SAP).

In the SAP, first, a seed layer made of copper is formed on an insulating layer by electroless plating. Next, a resist including a plurality of openings is formed on the seed layer. The plurality of openings are formed in respective areas corresponding to a plurality of Cu pillar bumps.

Next, the plurality of Cu pillar bumps made of copper are formed on the seed layer in the respective plurality of openings of the resist by electroplating. The resist is then removed to expose the seed layer. Finally, the exposed seed layer is etched using the plurality of Cu pillar bumps as a mask. The plurality of Cu pillar bumps are thus formed above the insulating layer.

### CITATION LIST

### Patent Literature

[PTL 1]

Japanese Patent No. 6960502

### SUMMARY OF INVENTION

### Technical Problem

In the conventional SAP described above, when the plurality of Cu pillar bumps are formed by electroplating, the height positions of the end faces of the plurality of Cu pillar bumps exposed from the respective plurality of openings of the resist vary relatively greatly due to the characteristics of electroplating. Consequently, when the semiconductor chip is mounted on the substrate, the Cu pillar bumps lower in height position do not contact the electrode pads on the semiconductor chip side. This is likely to cause a failure in the electrical connection between the semiconductor chip and the substrate.

The present disclosure has been made to solve such a problem, and has an object of providing a mounting substrate and a mounting substrate manufacturing method that can enhance reliability of electrical connection.

### Solution to Problem

In order to achieve the object stated above, a mounting substrate according to an aspect of the present disclosure is a mounting substrate including: an insulating layer; and a plurality of conductive bumps arranged on or above the insulating layer, wherein a variation in height position between a plurality of first end faces of the plurality of conductive bumps on a side opposite to the insulating layer is smaller than a variation in height position between a plurality of second end faces of the plurality of conductive bumps on a side where the insulating layer is located.

A mounting substrate manufacturing method according to an aspect of the present disclosure is a mounting substrate manufacturing method including: (a) preparing a plate member including a plurality of first openings that each have a first depth; (b) forming a plurality of conductive bumps respectively in the plurality of first openings of the plate member; (c) forming an insulating layer over end faces of the plurality of conductive bumps exposed respectively from the plurality of first openings, and the plate member; and (d) peeling off the plate member from the insulating layer.

### Advantageous Effects of Invention

A mounting substrate, etc. according to the present disclosure can enhance reliability of electrical connection.

### BRIEF DESCRIPTION OF DRAWINGS

FIG. 1 is a cross-sectional view of a mounting substrate according to Embodiment 1.

FIG. 2 is an enlarged cross-sectional view of a plurality of conductive bumps of the mounting substrate in FIG. 1.

FIG. 3 is a diagram for explaining a mounting substrate manufacturing method according to Embodiment 1.

FIG. 4 is a diagram for explaining a mounting substrate manufacturing method according to Comparative Example 1.

FIG. 5 is a cross-sectional view of a mounting substrate according to Embodiment 2.

FIG. 6 is a diagram for explaining a mounting substrate manufacturing method according to Embodiment 2.

FIG. 7 is a cross-sectional view of a mounting substrate according to Comparative Example 2.

FIG. 8 is a cross-sectional view of a mounting substrate according to Embodiment 3.

FIG. 9A is a diagram for explaining a mounting substrate manufacturing method according to Embodiment 3.

FIG. 9B is a diagram for explaining the mounting substrate manufacturing method according to Embodiment 3.

FIG. 9C is a diagram for explaining the mounting substrate manufacturing method according to Embodiment 3.

### DESCRIPTION OF EMBODIMENTS

Embodiments of the present disclosure will be described below, with reference to the drawings. The embodiments described below each show a specific example of the present disclosure. The numerical values, shapes, materials, structural elements, the arrangement and connection of the structural elements, etc. shown in the following embodiments are mere examples, and do not limit the scope of the present disclosure. Of the structural elements in the embodiments described below, the structural elements not recited in any one of the independent claims representing the broadest concepts of the present disclosure are described as optional structural elements.

Each drawing is a schematic and does not necessarily provide precise depiction. For example, scale and the like are not necessarily consistent throughout the drawings. The substantially same structural elements are given the same reference signs throughout the drawings, and repeated description is omitted or simplified.

### Embodiment 1

### [1-1. Structure of Mounting Substrate]

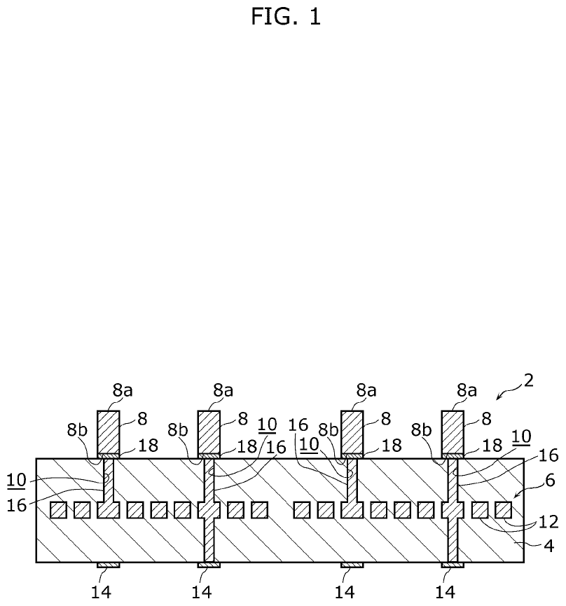

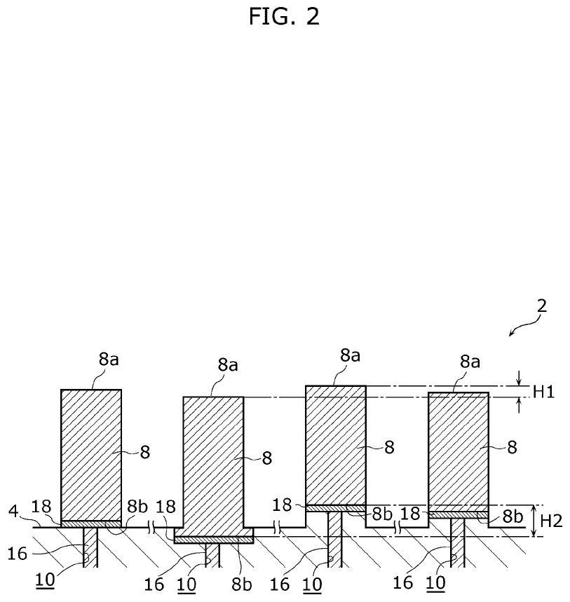

First, the structure of mounting substrate 2 according to Embodiment 1 will be described with reference to FIGS. 1 and 2. FIG. 1 is a cross-sectional view of mounting substrate 2 according to Embodiment 1. FIG. 2 is an enlarged cross-sectional view of a plurality of conductive bumps 8 of mounting substrate 2 in FIG. 1.

As illustrated in FIG. 1, mounting substrate 2 according to Embodiment 1 is, for example, an ultra-high-density semiconductor package substrate on which a semiconductor chip (not illustrated) is mounted. Mounting substrate 2 includes insulating layer 4, wiring body 6, and a plurality of conductive bumps 8.

Insulating layer 4 is located on a substrate (not illustrated). Insulating layer 4 functions as an interlayer insulating layer that electrically insulates part of wiring body 6 located at insulating layer 4 from the wiring layer of the substrate. Insulating layer 4 includes a plurality of via holes 10. Each of the plurality of via holes 10 extends from one surface (surface on the conductive bump 8 side) of insulating layer 4 in the thickness direction of insulating layer 4 (the vertical direction in FIG. 1). Insulating layer 4 is formed of an insulating material. In this embodiment, the insulating material forming insulating layer 4 is, for example, an insulating resin such as an epoxy resin or a polyimide resin.

Wiring body 6 includes a plurality of wirings 12, a plurality of electrodes 14, and a plurality of via electrodes 16. The plurality of wirings 12 are arranged inside insulating layer 4, and form a plurality of wiring layers. The plurality of electrodes 14 are arranged on the other surface (surface on the side opposite to conductive bumps 8) of insulating layer 4. Each of the plurality of electrodes 14 is electrically connected to wiring 12 or via electrode 16. The plurality of via electrodes 16 are located in the respective plurality of via holes 10 of insulating layer 4. Each of the plurality of via electrodes 16 is electrically connected to at least one of conductive bump 8, wiring 12, or electrode 14.

Each of the plurality of conductive bumps 8 is, for example, a columnar Cu pillar bump made of copper, and is an electroplating film formed by electroplating. Specifically, each of the plurality of conductive bumps 8 is an electrolytic Cu plating film formed of copper. Each of the plurality of conductive bumps 8 is located on or above insulating layer 4. The film thickness of each conductive bump 8 is 10 μm or more, for example.

End face 8a (an example of a first end face) of each of the plurality of conductive bumps 8 on the side opposite to insulating layer 4 is formed flat, and is electrically connected to an electrode pad of the semiconductor chip through a solder layer (not illustrated). End face 8b (an example of a second end face) of each of the plurality of conductive bumps 8 on the insulating layer 4 side (i.e. the side where insulating layer 4 is located) is formed flat, and contacts the one surface of insulating layer 4 with protective layer 18 therebetween.

Protective layer 18 is a layer for preventing, when forming the plurality of conductive bumps 8 on insulating layer 4 using a production plate as described later, the production plate and insulating layer 4 from adhering to each other. Protective layer 18 also functions as an interlayer conductive film for electrically connecting the plurality of conductive bumps 8 and the plurality of via electrodes 16. Protective layer 18 is located at the interface between each of the plurality of conductive bumps 8 and insulating layer 4. Protective layer 18 is an electroless plating film formed by electroless plating. Specifically, protective layer 18 is an electroless Cu plating film formed of copper. The film thickness of protective layer 18 is 100 nm or less, for example.

The plurality of via electrodes 16 are arranged directly below the respective plurality of conductive bumps 8. In other words, each of the plurality of conductive bumps 8 overlaps with a corresponding one of the plurality of via electrodes 16 in a plan view (i.e. as seen from a direction perpendicular to the one surface of insulating layer 4). Each of the plurality of conductive bumps 8 is thus electrically connected to corresponding via electrode 16 through protective layer 18.

The plurality of end faces 8a of the respective plurality of conductive bumps 8 on the side opposite to insulating layer 4 are illustrated to be at the same height position in FIG. 1, for the sake of convenience. Actually, however, there is small variation in height position between the plurality of end faces 8a, as illustrated in FIG. 2. The variation in height position between the plurality of end faces 8a is due to, for example, dimensional errors of the production plate when forming the plurality of conductive bumps 8 on insulating layer 4 using the production plate as described later. The variation in height position between the plurality of end faces 8a is so small that all of the plurality of end faces 8a can be electrically connected to the electrode pads of the semiconductor chip.

The plurality of end faces 8b of the respective plurality of conductive bumps 8 on the insulating layer 4 side are illustrated to be at the same height position in FIG. 1, for the sake of convenience. Actually, however, there is relatively large variation in height position between the plurality of end faces 8b, as illustrated in FIG. 2. The variation in height position between the plurality of end faces 8b is due to the characteristics of electroplating when forming the plurality of conductive bumps 8 on insulating layer 4 using the production plate as described later. In this specification, the term “height position” means the position from a reference position (for example, the other surface of insulating layer 4) in the thickness direction of mounting substrate 2 (i.e. the vertical direction in FIGS. 1 and 2).

As illustrated in FIG. 2, the variation in height position between the plurality of end faces 8a of the respective plurality of conductive bumps 8 on the side opposite to insulating layer 4 is smaller than the variation in height position between the plurality of end faces 8b of the respective plurality of conductive bumps 8 on the insulating layer 4 side. The variation in height position between the plurality of end faces 8a of the respective plurality of conductive bumps 8 on the side opposite to insulating layer 4 is represented by, for example, difference H1 between the maximum height position and the minimum height position of the plurality of end faces 8a from the reference position. Difference H1 is, for example, 1000 nm or less, more preferably 500 nm or less, and most preferably 200 nm or less. The variation in height position between the plurality of end faces 8b of the respective plurality of conductive bumps 8 on the insulating layer 4 side is represented by, for example, difference H2 between the maximum height position and the minimum height position of the plurality of end faces 8b from the reference position. Difference H2 is, for example, more than 1000 nm.

Although this embodiment describes the case where there is small variation in height position between the plurality of end faces 8a, the present disclosure is not limited to such. For example, the height positions of the plurality of end faces 8a can be made uniform by minimizing the dimensional errors of the production plate.

### [1-2. Mounting Substrate Manufacturing Method]

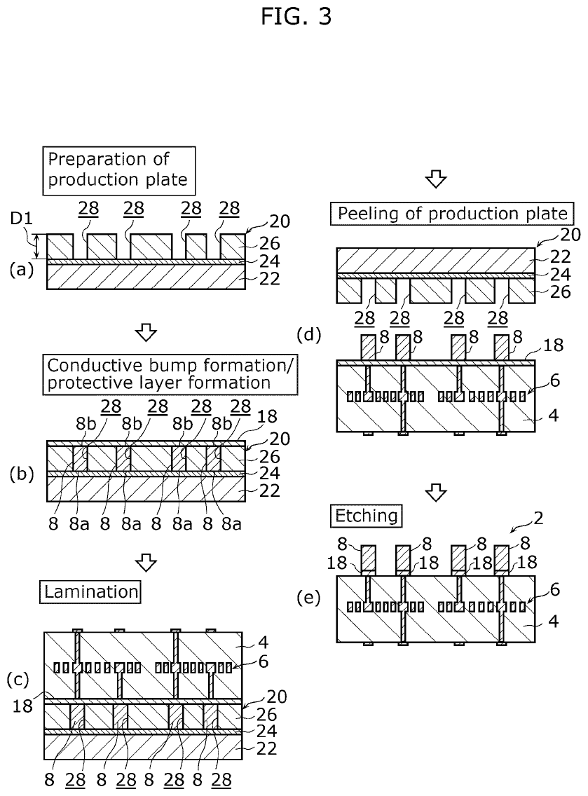

Next, a manufacturing method for mounting substrate 2 according to Embodiment 1 will be described with reference to FIG. 3. FIG. 3 is a diagram for explaining the manufacturing method for mounting substrate 2 according to Embodiment 1.

First, as illustrated in (a) in FIG. 3, production plate 20 (an example of a plate member) is prepared. Production plate 20 includes base material 22, seed layer 24, and insulating layer 26. Base material 22 is composed of, for example, a glass substrate or a metal substrate. Seed layer 24 is a seed electrode made of a conductive material for forming conductive bumps 8 by electroplating, and is located on base material 22. Insulating layer 26 is located on seed layer 24. Insulating layer 26 is formed of, for example, an insulating resin. Insulating layer 26 includes a plurality of openings 28 (an example of a first opening) for forming conductive bumps 8. Each of the plurality of openings 28 has first depth D1. Seed layer 24 is exposed in the plurality of openings 28.

Next, as illustrated in (b) in FIG. 3, an electrolytic Cu plating film made of copper is formed on seed layer 24 in openings 28 of insulating layer 26 of production plate 20 by electroplating. Thus, conductive bumps 8 as an electrolytic Cu plating film are formed on seed layer 24 in openings 28 of insulating layer 26 of production plate 20.

The height positions of end faces 8a of the plurality of conductive bumps 8 formed in the respective plurality of openings 28 of insulating layer 26 have small variation due to dimensional errors of production plate 20, etc., as mentioned above. In electroplating, when forming the plurality of conductive bumps 8 in the respective plurality of openings 28 of insulating layer 26, the height positions of end faces 8a of the plurality of conductive bumps 8 are regulated by the bottom (seed layer 24) of the respective plurality of openings 28. Therefore, the variation in height position between the plurality of end faces 8a is smaller than the variation in height position between the plurality of end faces 8b.

The height positions of end faces 8b of the plurality of conductive bumps 8 formed in the respective plurality of openings 28 of insulating layer 26 have relatively large variation due to the characteristics of electroplating, as mentioned above. In electroplating, when forming the plurality of conductive bumps 8 in the respective plurality of openings 28 of insulating layer 26, there is nothing to regulate the height positions of end faces 8b of the plurality of conductive bumps 8. This makes it difficult to control the film thickness of each of the plurality of conductive bumps 8 so that the height positions of end faces 8b of the plurality of conductive bumps 8 will be uniform.

Next, as illustrated in (b) in FIG. 3, an electroless Cu plating film made of copper is formed over end faces 8b of the plurality of conductive bumps 8 exposed from the respective plurality of openings 28 of insulating layer 26 of production plate 20 and insulating layer 26 of production plate 20 (i.e. the areas other than the areas of the plurality of openings 28 of insulating layer 26) by electroless plating. Thus, protective layer 18 as an electroless Cu plating film is formed over end faces 8b of the plurality of conductive bumps 8 and insulating layer 26 of production plate 20.

Next, as illustrated in (c) in FIG. 3, insulating layer 4 is laminated on protective layer 18. Wiring body 6 is formed in insulating layer 4 in advance. Hence, protective layer 18 is interposed between insulating layer 26 of production plate 20 and insulating layer 4.

In the step illustrated in (c) in FIG. 3, for example, the following transfer method may be used instead of laminating insulating layer 4 on protective layer 18. Specifically, insulating layer 4 in which wiring body 6 is formed in advance is prepared, and production plate 20 is set to face the one surface of insulating layer 4. Then, the plurality of conductive bumps 8 and protective layer 18 are separated from production plate 20 and transferred to the one surface of insulating layer 4 by a transfer method using, for example, hot pressing. Thus, end faces 8b of the plurality of conductive bumps 8 and protective layer 18 are transferred to the one surface of insulating layer 4, and the plurality of conductive bumps 8 and protective layer 18 are formed on insulating layer 4. In this case, production plate 20 is used as a transfer plate in the transfer method.

Next, as illustrated in (d) in FIG. 3, production plate 20 is peeled off from insulating layer 4. Here, since protective layer 18 is interposed between insulating layer 26 of production plate 20 and insulating layer 4, insulating layer 26 of production plate 20 and insulating layer 4 can be kept from adhering to each other, so that production plate 20 can be easily peeled off from insulating layer 4.

Next, as illustrated in (e) in FIG. 3, protective layer 18 exposed on insulating layer 4 is etched with an etching solution using the plurality of conductive bumps 8 as a mask. As a result, protective layer 18 exposed on insulating layer 4 is removed, and the plurality of conductive bumps 8 are formed above insulating layer 4. Mounting substrate 2 is produced in this way.

### [1-3. Effects]

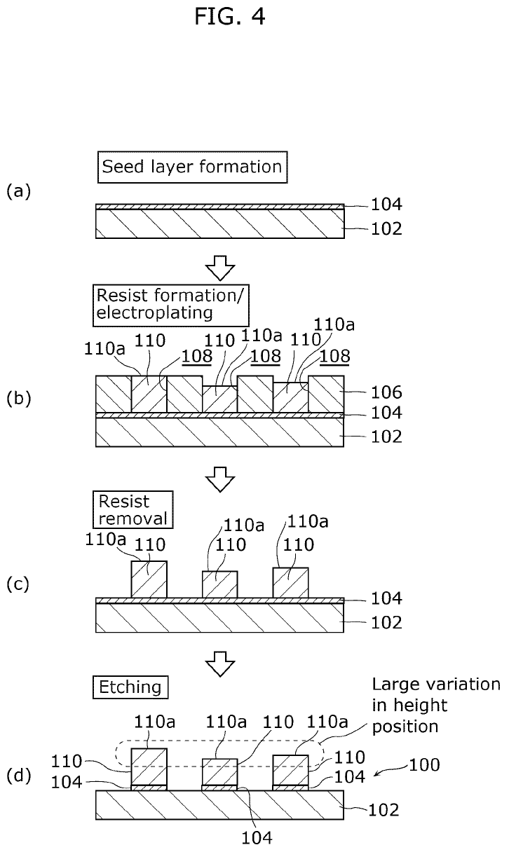

A manufacturing method for mounting substrate 100 according to Comparative Example 1 will be described with reference to FIG. 4. FIG. 4 is a diagram for explaining the manufacturing method for mounting substrate 100 according to Comparative Example 1.

First, as illustrated in (a) in FIG. 4, seed layer 104 as an electroless Cu plating film is formed on insulating layer 102 formed of an insulating resin by electroless plating. Next, as illustrated in (b) in FIG. 4, resist 106 including openings 108 is formed on seed layer 104. Conductive bumps 110 as an electrolytic Cu plating film are then formed on seed layer 104 in openings 108 of resist 106 by electroplating.

Next, as illustrated in (c) in FIG. 4, resist 106 is removed to expose seed layer 104. Finally, as illustrated in (d) in FIG. 4, exposed seed layer 104 is etched using the plurality of conductive bumps 110 as a mask. As a result, the plurality of conductive bumps 110 as Cu pillar bumps are formed above insulating layer 102. Mounting substrate 100 is produced in this way.

In this manufacturing method, when forming the plurality of conductive bumps 110 in the step illustrated in (b) in FIG. 4, there is nothing to regulate the height positions of end faces 110a of the plurality of conductive bumps 110 exposed from the respective plurality of openings 108 of resist 106. This makes it difficult to control the film thickness of each of the plurality of conductive bumps 110 so that the height positions of end faces 110a of the plurality of conductive bumps 110 will be uniform.

Consequently, the height positions of end faces 110a of the plurality of conductive bumps 110 vary greatly as illustrated in (d) in FIG. 4. Hence, when the semiconductor chip is mounted on mounting substrate 100, conductive bumps 110 lower in height position do not contact the electrode pads on the semiconductor chip side. This is likely to cause a failure in the electrical connection between the semiconductor chip and mounting substrate 100.

In this embodiment, on the other hand, mounting substrate 2 includes: insulating layer 4; and a plurality of conductive bumps 8 arranged on or above insulating layer 4. A variation in height position between a plurality of end faces 8a of the plurality of conductive bumps 8 on a side opposite to insulating layer 4 is smaller than a variation in height position between a plurality of end faces 8b of the plurality of conductive bumps 8 on a side where insulating layer 4 is located.

With this structure, when the semiconductor chip is mounted on mounting substrate 2, all of the plurality of conductive bumps 8 can contact the electrode pads on the semiconductor chip side. This enhances the reliability of the electrical connection between the semiconductor chip and mounting substrate 2.

Moreover, in this embodiment, insulating layer 4 includes via hole 10. Mounting substrate 2 further includes: via electrode 16 located in via hole 10, overlapping with specific conductive bump 8 of the plurality of conductive bumps 8 in a plan view, and electrically connected to specific conductive bump 8.

With this structure, specific conductive bump 8 and via electrode 16 can be electrically connected easily.

Moreover, in this embodiment, a manufacturing method for mounting substrate 2 includes: (a) preparing production plate 20 including a plurality of openings 28 that each have first depth D1; (b) forming a plurality of conductive bumps 8 respectively in the plurality of openings 28 of production plate 20; (c) forming insulating layer 4 over end faces 8a of the plurality of conductive bumps 8 exposed respectively from the plurality of openings 28, and production plate 20; and (d) peeling off production plate 20 from insulating layer 4.

With this method, the variation in height position between the plurality of end faces 8a of the respective plurality of conductive bumps 8 on the side opposite to insulating layer 4 can be made smaller than the variation in height position between the plurality of end faces 8b of the respective plurality of conductive bumps 8 on the insulating layer 4 side. Accordingly, when the semiconductor chip is mounted on mounting substrate 2, all of the plurality of conductive bumps 8 can contact the electrode pads on the semiconductor chip side. This enhances the reliability of the electrical connection between the semiconductor chip and mounting substrate 2.

### Embodiment 2

### [2-1. Structure of Mounting Substrate]

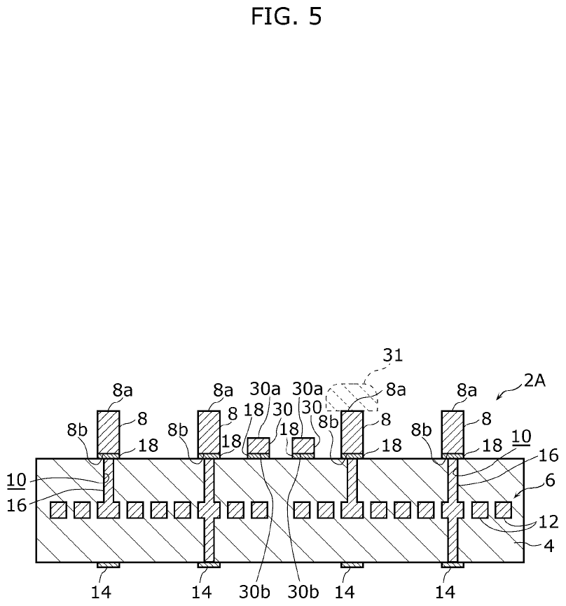

The structure of mounting substrate 2A according to Embodiment 2 will be described with reference to FIG. 5. FIG. 5 is a cross-sectional view of mounting substrate 2A according to Embodiment 2. In this embodiment, the same structural elements as those in Embodiment 1 described above are given the same reference signs and their description is omitted.

As illustrated in FIG. 5, mounting substrate 2A according to Embodiment 2 includes a plurality of wiring layers 30 in addition to the structural elements of mounting substrate 2 according to Embodiment 1.

Each of the plurality of wiring layers 30 is, for example, routed wiring that electrically connects two conductive bumps 8 or electrically connects conductive bump 8 and wiring 12. Each of the plurality of wiring layers 30 is an electroplating film formed by electroplating. Specifically, each of the plurality of wiring layers 30 is an electrolytic Cu plating film formed of copper. Each of the plurality of wiring layers 30 is located above insulating layer 4 with protective layer 18 therebetween. The film thickness of wiring layer 30 is 1 μm or more and 20 μm or less, for example.

The height positions of a plurality of end faces 30a (an example of a third end face) of the respective plurality of wiring layers 30 on the side opposite to insulating layer 4 are closer to insulating layer 4 than the height positions of the plurality of end faces 8a of the respective plurality of conductive bumps 8 on the side opposite to insulating layer 4 are.

### [2-2. Mounting Substrate Manufacturing Method]

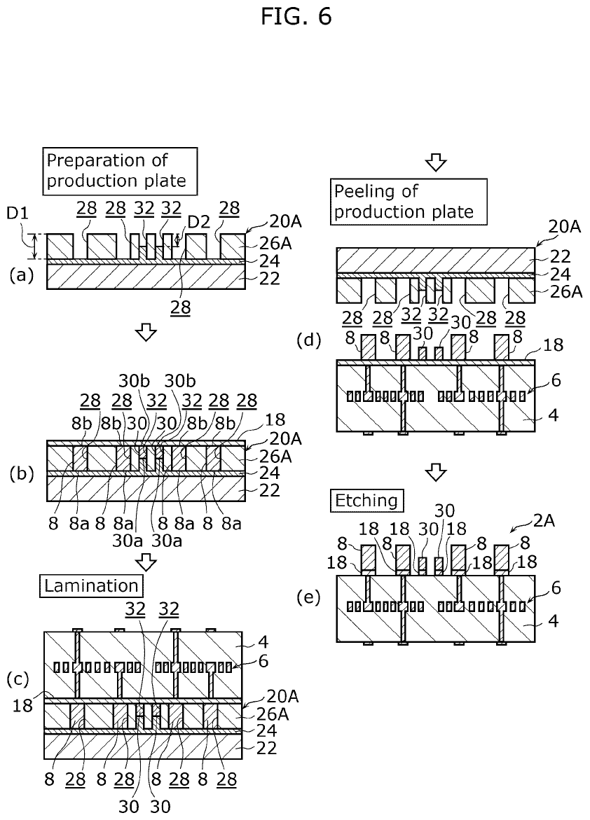

Next, a manufacturing method for mounting substrate 2A according to Embodiment 2 will be described with reference to FIG. 6. FIG. 6 is a diagram for explaining the manufacturing method for mounting substrate 2A according to Embodiment 2.

First, as illustrated in (a) in FIG. 6, production plate 20A is prepared. Insulating layer 26A of production plate 20A includes a plurality of openings 28 (an example of a first opening) for forming conductive bumps 8, and a plurality of openings 32 (an example of a second opening) for forming wiring layers 30. Each of the plurality of openings 28 has first depth D1. Each of the plurality of openings 32 has second depth D2 that is shallower than first depth D1. Seed layer 24 is exposed in the plurality of openings 28 and the plurality of openings 32. In detail, the bottom of second opening 32 is raised to be higher than the bottom of first opening 28 by seed layer 24.

Next, as illustrated in (b) in FIG. 6, an electrolytic Cu plating film made of copper is formed on seed layer 24 in openings 28 of insulating layer 26A of production plate 20A and on seed layer 24 in openings 32 of insulating layer 26A of production plate 20A by electroplating. Thus, conductive bumps 8 as an electrolytic Cu plating film are formed on seed layer 24 in openings 28 of insulating layer 26A of production plate 20A, and wiring layers 30 as an electrolytic Cu plating film are formed on seed layer 24 in openings 32 of insulating layer 26A of production plate 20A.

Next, as illustrated in (b) in FIG. 6, an electroless Cu plating film made of copper is formed over end faces 8b of the plurality of conductive bumps 8 exposed from the respective plurality of openings 28 of insulating layer 26A of production plate 20A, end faces 30b of the plurality of wiring layers 30 exposed from the respective plurality of openings 32 of insulating layer 26A of production plate 20A, and insulating layer 26A of production plate 20A by electroless plating. Thus, protective layer 18 as an electroless Cu plating film is formed over end faces 8b of the plurality of conductive bumps 8, end faces 30b of the plurality of wiring layers 30, and insulating layer 26A of production plate 20A.

Next, as illustrated in (c) in FIG. 6, insulating layer 4 is laminated on protective layer 18. Wiring body 6 is formed in insulating layer 4 in advance. Next, as illustrated in (d) in FIG. 6, production plate 20A is peeled off from insulating layer 4.

Next, as illustrated in (e) in FIG. 6, protective layer 18 exposed on insulating layer 4 is etched with an etching solution using the plurality of conductive bumps 8 and the plurality of wiring layers 30 as a mask. As a result, protective layer 18 exposed on insulating layer 4 is removed, and the plurality of conductive bumps 8 and the plurality of wiring layers 30 are formed above insulating layer 4. Mounting substrate 2A is produced in this way.

### [2-3. Effects]

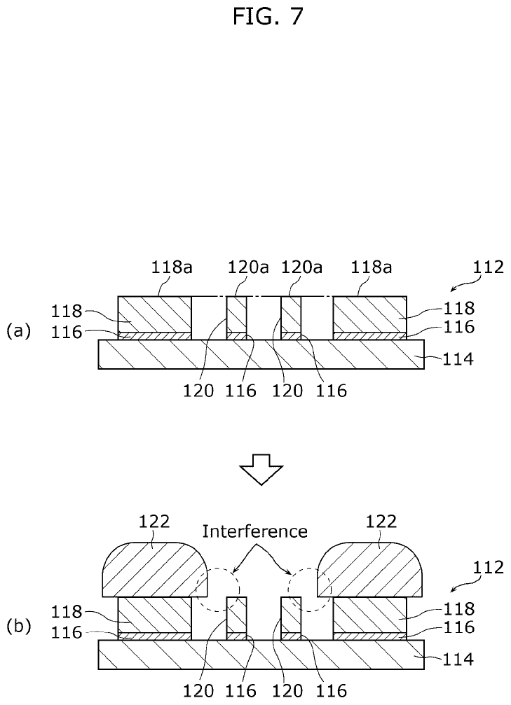

The structure of mounting substrate 112 according to Comparative Example 2 will be described with reference to FIG. 7. FIG. 7 is a cross-sectional view of mounting substrate 112 according to Comparative Example 2.

As illustrated in (a) in FIG. 7, mounting substrate 112 according to Comparative Example 2 includes insulating layer 114, a plurality of conductive bumps 118, and a plurality of wiring layers 120. Each of the plurality of conductive bumps 118 and the plurality of wiring layers 120 is formed above insulating layer 114 with seed layer 116 therebetween.

The height positions of the plurality of end faces 118a of the plurality of conductive bumps 118 on the side opposite to insulating layer 114 and the height positions of the plurality of end faces 120a of the plurality of wiring layers 120 on the side opposite to insulating layer 114 are approximately the same.

As illustrated in (b) in FIG. 7, in mounting substrate 112 according to Comparative Example 2, when solder layer 122 is formed on end face 118a of each of the plurality of conductive bumps 118, the distance between solder layer 122 and wiring layer 120 is relatively close. This is likely to cause interference (short circuit) between solder layer 122 and wiring layer 120. In order to avoid interference between solder layer 122 and wiring layer 120, the distance between solder layer 122 and wiring layer 120 needs to be increased. This hinders fine arrangement of the plurality of conductive bumps 118 and the plurality of wiring layers 120.

In this embodiment, on the other hand, mounting substrate 2A further includes: wiring layer 30 located on or above insulating layer 4. A height position of end face 30a of wiring layer 30 on the side opposite to insulating layer 4 is closer to insulating layer 4 than a height position of each of the plurality of end faces 8a is.

With this structure, when solder layer 31 is formed on end face 8a of each conductive bump 8, a sufficient distance between solder layer 31 and wiring layer 30 can be secured, as illustrated in FIG. 5. Hence, interference (short circuit) between solder layer 31 and wiring layer 30 can be suppressed while finely arranging the plurality of conductive bumps 8 and the plurality of wiring layers 30.

Moreover, in this embodiment, production plate 20A further includes opening 32 that has second depth D2 shallower than first depth D1. The manufacturing method for mounting substrate 20A further includes: (e) forming wiring layer 30 in opening 32 of production plate 20A. In (c), insulating layer 4 is formed over end faces 8b of the plurality of conductive bumps 8 exposed respectively from the plurality of openings 28, end face 30b of wiring layer 30 exposed from opening 32, and production plate 20A.

This allows conductive bumps 8 and wiring layer 30 to be formed in one step, so that mounting substrate 2A can be produced easily.

### Embodiment 3

### [3-1. Structure of Mounting Substrate]

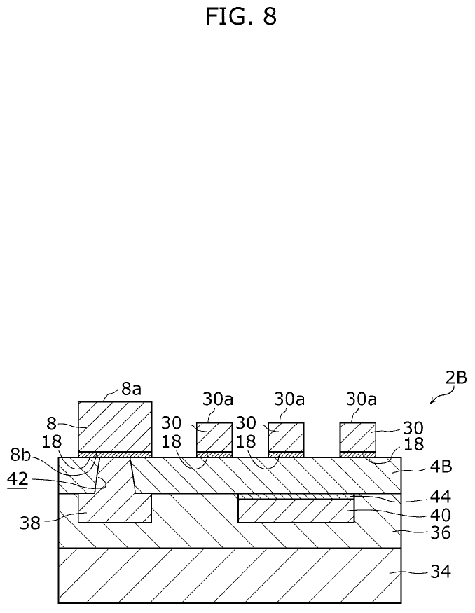

The structure of mounting substrate 2B according to Embodiment 3 will be described with reference to FIG. 8. FIG. 8 is a cross-sectional view of mounting substrate 2B according to Embodiment 3. In this embodiment, the same structural elements as those in Embodiments 1 and 2 described above are given the same reference signs and their description is omitted.

As illustrated in FIG. 8, mounting substrate 2B according to Embodiment 3 is, for example, a semiconductor package substrate including a plurality of wiring layers in which wiring is formed. Mounting substrate 2B includes supporting base material 34, adhesive member 36, insulating layer 4B, conductive bump 8, a plurality of wiring layers 30, via electrode 38, and conductor 40.

Supporting base material 34 is a member that serves as the base of mounting substrate 2B. Supporting base material 34 is formed of an insulating material such as an insulating resin, and is set to face a motherboard (not illustrated).

Adhesive member 36 is located on supporting base material 34. Adhesive member 36 is a member for bonding supporting base material 34 and insulating layer 4B to each other.

Insulating layer 4B is located above supporting base material 34 with adhesive member 36 therebetween. Insulating layer 4B includes via hole 42. Via electrode 38 is located in via hole 42. Via hole 42 has a truncated cone shape with a tapered inner surface.

Conductive bump 8 is located on or above insulating layer 4B. Specifically, conductive bump 8 is located so as to contact one surface of insulating layer 4B with protective layer 18 therebetween, and is located above supporting base material 34 with insulating layer 4B and adhesive member 36 therebetween. Although only one conductive bump 8 is illustrated in FIG. 8 for the sake of convenience, actually a plurality of conductive bumps 8 are arranged on or above insulating layer 4B.

The plurality of wiring layers 30 are located on or above insulating layer 4B. Specifically, each of the plurality of wiring layers 30 is located so as to contact the one surface of insulating layer 4B with protective layer 18 therebetween, and is located above supporting base material 34 with insulating layer 4B and adhesive member 36 therebetween.

Via electrode 38 is at least partially located in via hole 42 of insulating layer 4B. Specifically, via electrode 38 is embedded in via hole 42 without any gaps. Via electrode 38 not only is located in via hole 42 but also protrudes from the other surface (surface on the supporting base material 34 side) of insulating layer 4B. Via electrode 38 is electrically connected to end face 8b of conductive bump 8 through protective layer 18.

Conductor 40 is a wiring, electrode, or the like formed in a wiring layer other than wiring layers 30. Conductor 40 is located so as to contact the other surface of insulating layer 4B with seed layer 44 therebetween. Seed layer 44 is a seed electrode made of a conductive material for forming conductor 40 by electroplating.

### [3-2. Mounting Substrate Manufacturing Method]

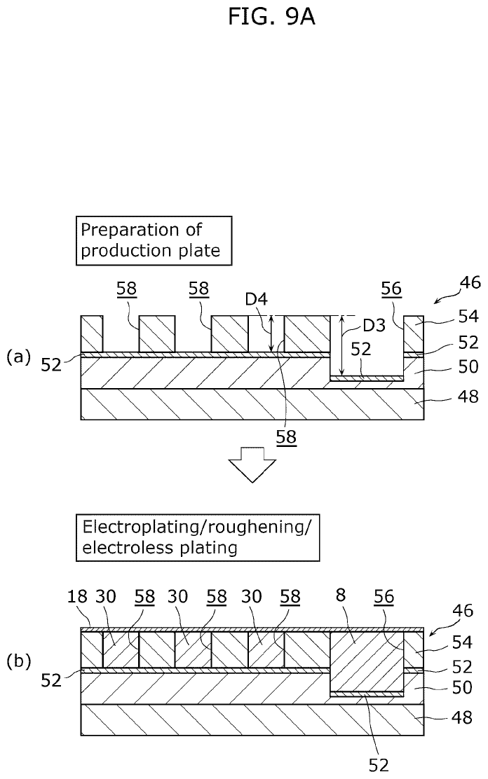

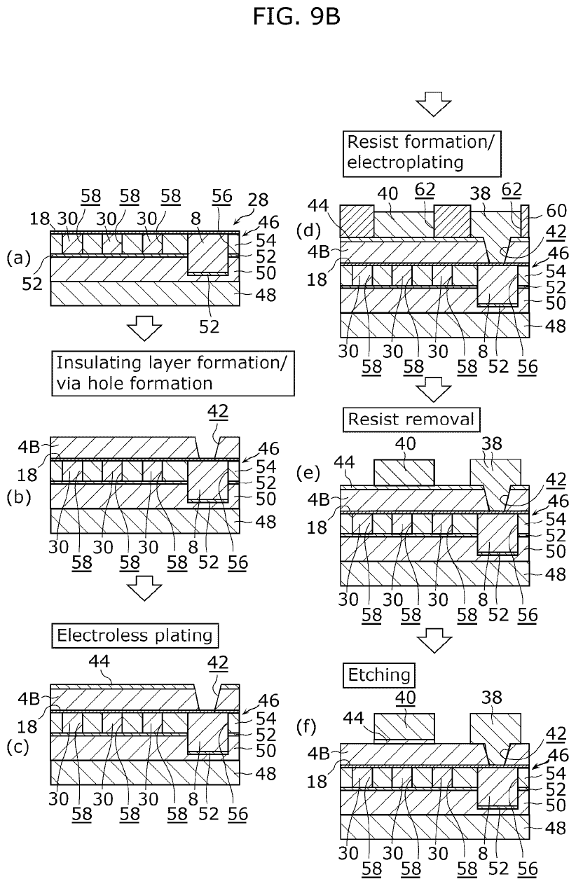

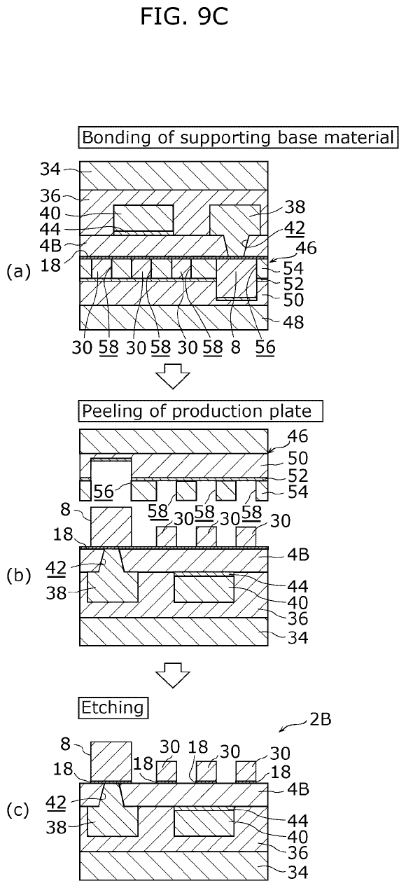

A manufacturing method for mounting substrate 2B according to Embodiment 3 will be described with reference to FIGS. 9A to 9C. FIGS. 9A to 9C are diagrams for explaining the manufacturing method for mounting substrate 2B according to Embodiment 3.

First, a process of forming the first wiring layer will be described with reference to FIG. 9A. As illustrated in (a) in FIG. 9A, production plate 46 (an example of a plate member) is prepared. Production plate 46 includes base material 48, release layer 50, seed layer 52, and insulating layer 54. Base material 48 is composed of, for example, a glass substrate or a metal substrate. Release layer 50 is a layer for peeling conductive bump 8 and the plurality of wiring layers 30 from production plate 46, and is located on base material 48. Seed layer 52 is a seed electrode made of a conductive material for forming conductive bump 8 and the plurality of wiring layers 30 by electroplating, and is located on release layer 50.

Insulating layer 54 is located on seed layer 52. Insulating layer 54 is formed of, for example, an insulating resin. Insulating layer 54 and release layer 50 include opening 56 (an example of a first opening) for forming conductive bump 8. Seed layer 52 is exposed in opening 56. Insulating layer 54 also includes a plurality of openings 58 (an example of a second opening) for forming the respective plurality of wiring layers 30. Opening 56 has first depth D3. Each of the plurality of openings 58 has second depth D4 that is shallower than first depth D3. Seed layer 52 is exposed in each of the plurality of openings 58. Although only one opening 56 is illustrated in FIGS. 9A to 9C for the sake of convenience, actually insulating layer 54 includes a plurality of openings 56.

Next, as illustrated in (b) in FIG. 9A, an electrolytic Cu plating film made of copper is formed on seed layer 52 in openings 56 of insulating layer 54 and release layer 50 of production plate 46 by electroplating. Thus, conductive bumps 8 as an electrolytic Cu plating film are formed on seed layer 52 in openings 56 of insulating layer 54 and release layer 50 of production plate 46. Moreover, an electrolytic Cu plating film made of copper is formed on seed layer 52 in openings 58 of insulating layer 54 of production plate 46 by electroplating. Thus, wiring layers 30 as an electrolytic Cu plating film are formed on seed layer 52 in openings 58 of insulating layer 54 of production plate 46.

Finally, an electroless Cu plating film made of copper is formed over the end faces of conductive bumps 8 exposed from openings 56 of insulating layer 54 of production plate 46, the end faces of wiring layers 30 exposed from openings 58 of insulating layer 54 of production plate 46, and insulating layer 54 of production plate 46 (i.e. the areas other than the areas of openings 56 and 58 of insulating layer 54) by electroless plating. Thus, protective layer 18 as an electroless Cu plating film is formed over the end faces of conductive bumps 8, the end faces of wiring layers 30, and insulating layer 54 of production plate 46.

Next, a process of forming the second wiring layer will be described with reference to FIG. 9B. As illustrated in (a) and (b) in FIG. 9B, for example, a transfer method is used to transfer conductive bumps 8, wiring layers 30, and protective layer 18 to the one surface of insulating layer 4B, thus forming conductive bumps 8, wiring layers 30, and protective layer 18 on insulating layer 4B. Here, part of insulating layer 4B is removed to form via hole 42 in insulating layer 4B. For example, via hole 42 can be formed by applying a laser from above conductive bump 8 to remove part of insulating layer 4B. As a result of forming via hole 42 in insulating layer 4B in this way, part of protective layer 18 is exposed.

Next, as illustrated in (c) in FIG. 9B, an electroless Cu plating film made of copper is formed on insulating layer 4B by electroless plating. Thus, seed layer 44 as an electroless Cu plating film is formed on insulating layer 4B. Seed layer 44 may be formed by sputtering instead of electroless plating.

Next, as illustrated in (d) in FIG. 9B, resist 60 is selectively formed on seed layer 44. Resist 60 includes a plurality of openings 62. The plurality of openings 62 expose predetermined areas of seed layer 44 and via holes 42 of insulating layer 4B. That is, via holes 42 of insulating layer 4B communicate with openings 62. An example of resist 60 is a dry film resist (DFR).

Next, an electrolytic Cu plating film made of copper is formed on seed layer 44 in opening 62 of resist 60 and on protective layer 18 in opening 62 of resist 60 and in via hole 42 of insulating layer 4B by electroplating. Thus, conductor 40 as an electrolytic Cu plating film is formed on seed layer 44 in opening 62 of resist 60, and via electrode 38 as an electrolytic Cu plating film is formed on protective layer 18 in opening 62 of resist 60 and in via hole 42 of insulating layer 4B.

Next, as illustrated in (e) in FIG. 9B, resist 60 is removed. Specifically, resist 60, which is a dry film resist, is peeled off from seed layer 44. This exposes the part of seed layer 44 covered by resist 60.

Finally, as illustrated in (f) in FIG. 9B, seed layer 44 exposed on insulating layer 4B is etched with an etching solution using conductor 40 as a mask. As a result, seed layer 44 exposed on insulating layer 4B is removed.

Next, a process of processing the back surface (surface facing the motherboard) of mounting substrate 2B will be described with reference to FIG. 9C. First, as illustrated in (a) in FIG. 9C, supporting base material 34 and insulating layer 4B are bonded to each other via adhesive member 36. Next, as illustrated in (b) in FIG. 9C, production plate 46 is peeled off from insulating layer 4B. Finally, as illustrated in (c) in FIG. 9C, protective layer 18 exposed on insulating layer 4B is etched with an etching solution using conductive bump 8 and the plurality of wiring layers 30 as a mask. As a result, protective layer 18 exposed on insulating layer 4B is removed, and conductive bump 8 and the plurality of wiring layers 30 are formed above insulating layer 4B. Mounting substrate 2B is produced in this way.

### [3-3. Effects]

This embodiment can achieve the same effects as Embodiment 1.

### (Variations)

A mounting substrate, etc. according to the present disclosure have been described by way of the embodiments above, but the present disclosure is not limited to the foregoing embodiments. Other modifications obtained by applying various changes conceivable by a person skilled in the art to each embodiment and any combinations of the structural elements and functions in each embodiment without departing from the scope of the present disclosure are also included in the present disclosure.

### Industrial Applicability

A mounting substrate according to the present disclosure can be used, for example, as a semiconductor package substrate.

### REFERENCE SIGNS LIST

2, 2A, 2B, 100, 112 mounting substrate
4, 4B, 26, 26A, 54, 102, 114 insulating layer
6 wiring body
8, 110, 118 conductive bump
8a, 8b, 30a, 30b, 110a, 118a, 120a end face
10, 42 via hole
12 wiring
14 electrode
16, 38 via electrode
18 protective layer
20, 20A, 46 production plate
22 base material
24, 44, 52, 104, 116 seed layer
28, 32, 56, 58, 62, 108 opening
30, 120 wiring layer
31, 122 solder layer
34 supporting base material
36 adhesive member
40 conductor
48 base material
50 release layer
60, 106 resist

1. A mounting substrate comprising:
an insulating layer; and
a plurality of conductive bumps arranged on or above the insulating layer,
wherein a variation in height position between a plurality of first end faces of the plurality of conductive bumps on a side opposite to the insulating layer is smaller than a variation in height position between a plurality of second end faces of the plurality of conductive bumps on a side where the insulating layer is located.

2. The mounting substrate according to claim 1, further comprising:
a wiring layer located on or above the insulating layer,
wherein a height position of a third end face of the wiring layer on the side opposite to the insulating layer is closer to the insulating layer than a height position of each of the plurality of first end faces is.

3. The mounting substrate according to claim 1,
wherein the insulating layer includes a via hole, and
the mounting substrate further comprises:
a via electrode located in the via hole, overlapping with a specific conductive bump of the plurality of conductive bumps in a plan view, and electrically connected to the specific conductive bump.

4. A mounting substrate manufacturing method comprising:
(a) preparing a plate member including a plurality of first openings that each have a first depth;
(b) forming a plurality of conductive bumps respectively in the plurality of first openings of the plate member;
(c) forming an insulating layer over end faces of the plurality of conductive bumps exposed respectively from the plurality of first openings, and the plate member; and
(d) peeling off the plate member from the insulating layer.

5. The mounting substrate manufacturing method according to claim 4,
wherein the plate member further includes a second opening that has a second depth shallower than the first depth,
the mounting substrate manufacturing method further comprises:
(e) forming a wiring layer in the second opening of the plate member, and
in (c), the insulating layer is formed over the end faces of the plurality of conductive bumps exposed respectively from the plurality of first openings, an end face of the wiring layer exposed from the second opening, and the plate member.
